(19) United States
(12) Patent Application Publication
(10) Pub. No.: US 2014/0111239 A1
(43) Pub. Date: Apr. 24, 2014

(54) LOCALIZED PRINTED CIRCUIT BOARD LAYER EXTENDER APPARATUS FOR RELIEVING LAYER CONGESTION NEAR HIGH PIN-COUNT DEVICES

(71) Applicant: QUALCOMM INCORPORATED, San Diego, CA (US)

(72) Inventors: James L. Blair, Ramona, CA (US); John A. Kolano, San Diego, CA (US)

(73) Assignee: QUALCOMM INCORPORATED, San Diego, CA (US)

(21) Appl. No.: 13/692,897

(22) Filed: Dec. 3, 2012

Related U.S. Application Data
(60) Provisional application No. 61/716,860, filed on Oct. 22, 2012.

(51) Int. Cl. G01R 1/04

(52) U.S. Cl. CPC G01R 1/0483
USPC 324/756.02

(57) ABSTRACT

A method and apparatus for a localized printed circuit board layer extender (LLX) is provided. The apparatus relieves layer routing congestion in and around high pin count integrated circuits. The method begins when a localized layer extender is provided that is compatible with the bottom-side pin-field of a device under test (DUT). The LLX is affixed to the bottom-side pin-field of the DUT. Test signals are then routed through the LLX as part of a test procedure. The apparatus includes: a LLX that substantially matches the pin-field of a bottom side of a DUT; a LLX base; and a LLX debug interface.

### CROSS-REFERENCE TO RELATED APPLICATION(S)

This application claims the benefit of U.S. Provisional Application Ser. No. 61/716,860, entitled “Localized Printed Circuit Board Layer Extender Apparatus for Relieving Layer Congestion Near High Pin-Count Devices” and filed on Oct. 22, 2012, which is expressly incorporated by reference herein in its entirety

### BACKGROUND

1. Field

The present disclosure relates generally to testing electronic packages, and more particularly, to localized printed circuit board layer extender apparatus for relieving layer routing congestion in and around high pin-count integrated circuits.

2. Background

The electrical interfaces (I/O) of modern integrated circuit (IC) devices have become very crowded, often with over 1000 or more pins placed densely in a pin array. This has forced the pitch between pins to be 0.4 or even smaller. Connecting to such small pin arrays has become problematic, and not merely for cell phones, but for many other electronic devices. Testing these dense IC devices has also become even more of a challenge and requires specialized multi-layer printed circuit boards (test-PCBs) with multiple conductive layers. The number of conductive layers may range from the low twenties for a 1× device under test (DUT) IC test board to over forty layers for 8×DUT configurations. With an imminent shift to test-PCBs of 16×DUTS or more, layer counts are expected to increase greatly in order to handle large numbers of high pin count devices that must be tested.

In the past, DUT signals were connected to test PCB devices by breaking out within the horizontal layers of the PCB under the device footprint. This has resulted in congested routing in and around the DUT area, which contributes to crosstalk, impedance control, voltage drops, compromises in critical component proximity, and power delivery issues. Routing congestion forces the total layer count for the PCB to increase, escalating both recurring and non-recurring costs and decreasing the mean time between failure (MTBF), and may also compromise board fabrication yield. One key contributor to routing congestion near each DUT site are a subset of signals that lack exotic test evaluation and are subject only to die-to-pin signal continuity checks, and in some cases, a check of die I/O driver electrical drive strength. For each DUT literally hundreds of these signals need only to be multiplexed for input into a limited number of test platform resources. In many cases this plethora of DUT signals are routed out and away from the DUT sites, often to remote multiplexer (MUX) functions on the test-PCB. This may result in critical test DUT signal routing being compromised when it must negotiate a dense thicket of high count but low priority signals.

There is a need in the art for a method and apparatus for reducing near DUT signal routing congestion and to promote an increase in test-PCB multi-DUT density.

### SUMMARY

Embodiments disclosed herein provide a method and apparatus for facilitating testing of an electronic device. The method begins when a localized layer extender is provided that is compatible with the bottom-side pin-field of a device under test (DUT). The LLX is affixed to the bottom-side pin-field of the DUT. Test signals are then routed through the LLX as part of a test procedure.

A further embodiment provides an apparatus for testing an electronic device. The apparatus includes: a LLX that substantially matches the pin-field of a bottom side of a DUT; a LLX base; and a LLX debug interface.

Yet a further embodiment provides an apparatus for testing a package-on-package device. The apparatus comprises: means for providing a localized layer extender (LLX) compatible with a bottom-side pin-field of a device under test (DUT); means for affixing the LLX to the bottom side pin-field of the DUT; and means for routing signals through the LLX as part of a test procedure.

### BRIEF DESCRIPTION OF THE DRAWINGS

FIG. 1 illustrates the side view of a localized PCB layer extender apparatus according to embodiments of the disclosure.

FIG. 2 depicts the component side view of a localized layer extender apparatus according to embodiments of the disclosure.

FIG. 3 illustrates a PCB test assembly according to embodiments of the disclosure.

FIG. 4 is a flowchart of a method of using a localized layer extender apparatus to facilitate testing, according to embodiments of the disclosure.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

Embodiments disclosed herein reduce near DUT signal routing congestion by affixing small circuit board modules, known as localized PCB layer extenders (LLX) through an attachment such as solder, or other suitable mounting mechanism, directly to the existing DUT using the thru-vias present on the bottom layer of the test-PCB. All signals to be multiplexed together (or those that may require special handling, such as for isolation purposes) are directed into the LLX and are aggregated by solid state or passive means, and then output from a compact number of LLX output signals. Each LLX removes hundreds of signals per DUT from the main test-PCB and frees up a significant amount of routing space. The LLX module thus physically diverts signals down and away from the DUT pin array and returns a limited signal count back to the test-PCB, thus reducing the amount of signal routing required. This routing space may then be made available for critical test signals for each DUT. In addition, considerable cost savings is achieved through reductions in test-PCB layout time and effort (leading to shortened development cycles) as well as recurring costs associated with a reduced layer count.

This LLX apparatus embodies a circuit board module that consists of a sequentially laminated multi-layer “base” to a “top” PCB in a single integrated unit. In order to preserve signal integrity characteristics that are achieved on the main test-PCB, the LLX may be fabricated from identical or similar board materials, having the same dielectric constant, copper conductivity, loss tangent, and other similar characteristics. For non-critical applications, inexpensive materials such as FR-4 may be used. The LLX base-PCB is provisioned with a via-in-pad connection field array substantially identical to the DUT thru-via pin field present on the test-PCB side B layer. The base-PCB construction may yield high signal integrity coaxial signal conduit characteristics if required. This base-PCB thickness is used to elevate the LLX top-PCB out and away from the test-PCB near DUT side B mounted components and is laminated onto the top-PCB, forming an integrated assembly. The top-PCB serves DUT signal accretion and dissemination breakout and also serves as a component attachment plane. Signal breakout may exploit a combination of blind, through, and buried via structures to maximize top-PCB circuit density.

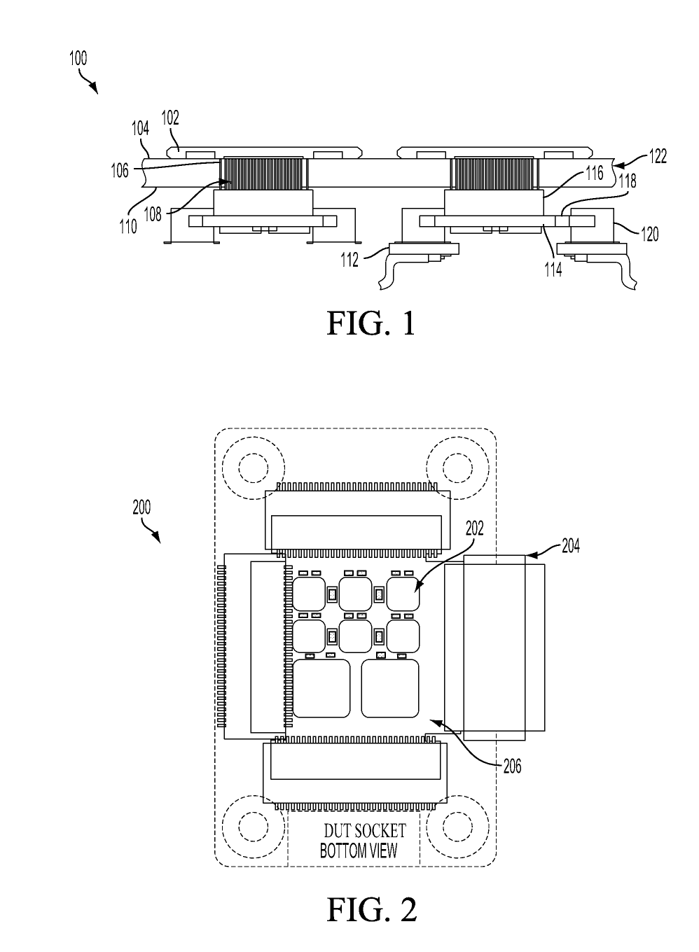

FIG. 1 shows a side view of an LLX device in accordance with embodiments described herein. The assembly 100 includes the DUT socket 102 mounted on side A 104 of test-PCB 122. In an embodiment an extra pin row 106 is provided as part of the DUT ball grid array (BGA) 108 pin array. The LLX top-PCB component surface 114 (opposite the base-PCB 116 attachment plane 110) permits the addition of both active and passive components, such as multiplexer integrated circuits (IC) using standard surface mount technology (SMT) techniques. The base of the fully assembled LLX module is then fitted with conductive BGA contacts that may be attached using solder, ultrasonic welding, or other means, directly to the test-PCB side B 108 BGA field. LLX BGA balls and pin pads may be omitted over DUT load sensitive signals. The completed LLX module is fully SMT compatible. As illustrated in FIG. 1, the LLX base 116 fits within or slightly outside the DUT pin field on the test-PCB 110. The LLX directs multiple selected DUT signals down and away from the heavily congested test-PCB 122. The LLX also includes an electrical interface 118 option for critical signal ingress and egress, debug I/O, or similar functionality and an optional electrical connector 120. The connector 120 may be connected to the test-PCB using a flexible cable 112 or optically over modulated light interconnect (not shown). For wideband hard wired applications, cable 112 may be of a coaxial type, coplanar waveguide (CPWG) or grounded coplanar waveguide (GCPWG) flexible PCB interconnect type, or other cabling with similar characteristics may be used. For low bandwidth applications, general purpose ribbon cable may be utilized. The LLX electrical interface may be used to connect the LLX to remote test-PCB attachment points or for LLX/test-PCB debug purposes.

One embodiment of the LLX provides output/power/control connection means through any one or combination of the following methods: including an extra pin row 106 just outside the DUT BGA field 108 on both the LLX base-PCB 116 and test-PCB 110 surface; capturing unused, no connection (NC) DUT pins and using them as an LLX connection resource; using vacant DUT BGA rows and/or columns for LLX resource connections; and connecting via coaxial ribbon cable 112 or similar means, to one or more LLX electrical connections for each DUT via mating connector 120 to test-PCB connections located well outside the immediate area of the DUT. Apart from the output/power/control connection means described above, the LLX grounding is intimately secured to the DUT through the plethora of DUT BGA pin field ground connections bonded to it.

A further embodiment provides that if extremely small parts such as 0201/01005 sized resistors and capacitors are needed and must be attached between DUT pins on the test-PCB side B 110, the LLX assembly may have pockets milled into the base-PCB BGA surface 116 allowing these small components to be pre-attached to the test-PCB 110, to recess into the LLX base during attachment to test-PCB 110.

In accordance with an embodiment, the optional LLX electrical interface may serve as an optional debug test interface access to external test equipment.

In a still further embodiment, the LLX assembly may be provided with a top-PCB connector 120 interface. FIG. 1 and FIG. 2 illustrate card edge-type connectors 120 and 204 that may provide for one or more cables 112 to be attached. The other cable end may be passed to side A of the test-PCB through a conveniently located slot in the board and then affixed to a signal breakout PCB or similar device. The cable may also be attached to a test-PCB on-board breakout interface. As illustrated in FIG. 2, up to four debug cables per DUT may be connected to the breakout board interface, thus providing for a four-sided LLX top-PCB. For those of skill in the art, it is understood that any physically small connector type could serve as a suitable electrical interface and/or debug LLX top-PCB connection means.

FIG. 2 illustrates a top view of a LLX in accordance with embodiments described herein. The assembly 200, shows the LLX signal handling/processing components 202 and the four card edge connectors 204. The LLX provides top-PCB area sufficient to allow six 8:1 and two 32:1 multiplexers (MUXs) or up to six 32:1 MUXs (not shown) to be mounted on the LLX 206, as described above. As illustrated, the LLX debug option is capable of serving in excess of 200 signals. The debug interface connection may be used to remotely convey test signals out and away from the DUT to remote test-PCB locations. This embodiment provides for eliminating return signals near the DUT, avoiding cross talk and other signal contamination issues.

An additional benefit from the LLX is that test-PCB “picket fence” routing barriers caused by both low priority aggregation as well as high priority function MUX IC connection vias are removed.

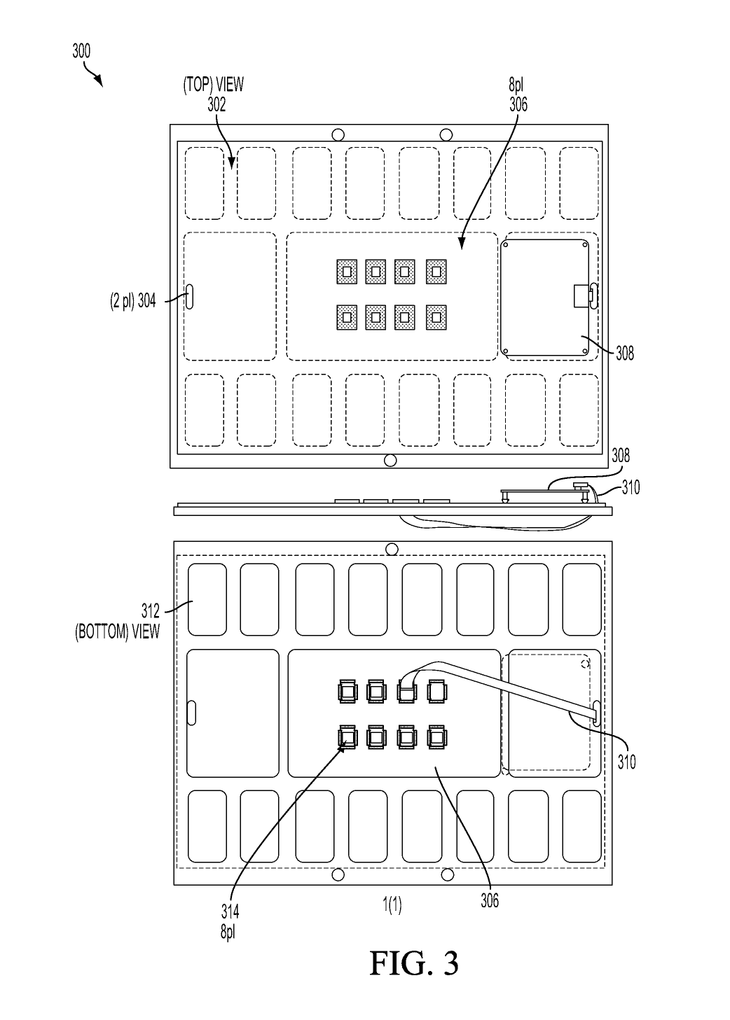

FIG. 3 illustrates top, side, and bottom views of a test-PCB and LLX according to embodiments described herein. The assembly 300 includes both top view 302, bottom view 312 of a test-PCB and an exemplary LLX debug breakout-PCB 308. The DUTs 306 to be tested as located as shown, however, the test-PCB may utilize a different arrangement. The LLX debug breakout-PCB 308 is shown located near one edge of the test-PCB top surface. Cable 310 is used in the embodiment illustrated in FIG. 3 and passes through slot 304. Multiple slots 304 may be used, as shown in FIG. 3. The side view depicts the routing of the debug breakout-PCB attachment cable 310 through the slot to access the bottom side connectors of the DUTs LLXs 314.

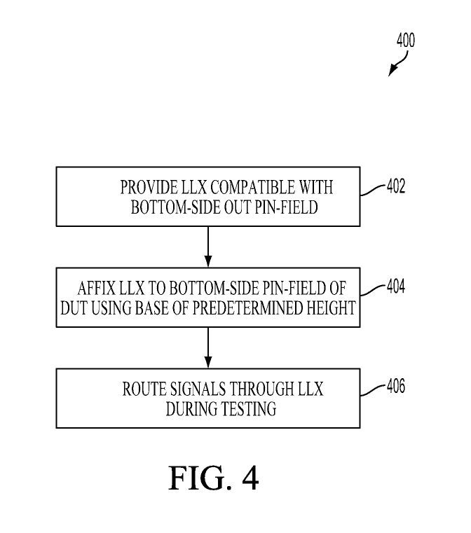

FIG. 4 presents a method 400, for using an LLX as part of a testing procedure. The method begins with step 402 where a LLX is provided. The LLX is compatible with the bottom-side pin-field of the DUT. In step 404 the LLX is affixed to the bottom-side pin-field of the DUT using a base_PCB of a predetermined thickness. The base thickness may achieve any suitable height below and away from the DUT and may vary depending on the application and the devices being tested. In step 406 signals are routed through the LLX in accordance with the test procedure.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

1. A method for testing an electronic device, comprising:
providing a localized layer extender (LLX) compatible with a bottom-side pin-field of a device under test (DUT);
affixing the LLX to the bottom-side pin-field of the DUT; and
routing signals through the LLX as part of a test procedure.

2. The method of claim 1, wherein the LLX is affixed to the bottom-side pin-field of the DUT with a base of predetermined thickness.

3. The method of claim 1 wherein the LLX includes a signal connector interface.

4. The method of claim 3 wherein the LLX signal interface includes a debug connector interface.

5. The method of claim 1 wherein the LLX fits within the DUT pin-field footprint.

6. The method of claim 5 wherein the LLX uses unused, no connection (NC) DUT pins for an LLX connection resource.

7. The method of claim 5 wherein the LLX uses vacant DUT ball grid array (BGA) rows for an LLX connection resource.

8. The method of claim 5 wherein the LLX uses vacant DUT ball grid array (BGA) columns for an LLX connection resource.

9. The method of claim 5 wherein the LLX connection resource is an attached cable.

10. The method of claim 1 wherein the LLX fits outside the DUT pin-field footprint.

11. The method of claim 10 wherein the LLX connection resources are outside the DUT pin-field footprint.

12. The method of claim 1 wherein the selected LLX pin connections are omitted opposite selected pins in the bottom-side DUT pin-field.

13. An apparatus for testing an electronic device, comprising:
a localized layer extender (LLX) board substantially matching a pin-field of a bottom-side of a device under test (DUT);
a LLX base;
a LLX top electrical component mounting surface;
a LLX electrical interface; and
a LLX debug interface.

14. The apparatus of claim 13 further comprising an LLX signal connector mounted to the LLX electrical interface.

15. The apparatus of claim 13 further comprising an LLX debug connector mounted to the LLX electrical interface.

16. The apparatus of claim 13 wherein the LLX base provides pockets on an LLX ball grid array (BGA) surface.

17. The apparatus of claim 13 wherein the LLX top provides an electrical component mounting surface.

18. An apparatus for testing an electronic device, comprising:
means for providing a localized layer extender (LLX) compatible with a bottom-side pin-field of a device under test (DUT);
means for affixing the LLX to the bottom side pin-field of the DUT; and
means for routing signals through the LLX as part of a test procedure.

19. The apparatus of claim 18, wherein the means for affixing the LLX to the bottom-side pin-field of the DUT incorporates a base of predetermined thickness.

20. The apparatus of claim 18, wherein the means for providing a localized layer extender (LLX) includes a signal connector interface.

21. The apparatus of claim 20, wherein the means for providing a localized layer extender (LLX) includes a debug connector interface.

22. The apparatus of claim 18, wherein the means for providing a localized layer extender (LLX) includes an electronic component mounting surface.
